(19) United States
(12) Patent Application Publication
(10) Pub. No.: US 2006/0006466 A1
(43) Pub. Date: Jan. 12, 2006

(54) Semiconductor device and method of manufacturing the same

(76) Inventor: Toshihiko Iinuma, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/154,646

(22) Filed: Jun. 17, 2005

(30) Foreign Application Priority Data
Jun. 22, 2004 (JP) 2004-183767

(51) Int. Cl. H01L 27/01

(52) U.S. Cl. 257/347

(57) ABSTRACT

A semiconductor device comprises a support substrate, an insulation film provided on the support substrate, a rectangular silicon island provided on the insulation film, the rectangular silicon island having first side surfaces mutually opposed in a first direction and second side surfaces mutually opposed in a second direction perpendicular to the first direction, an insulation layer provided on an upper surface of the silicon island, a gate insulation film provided on the mutually opposed first side surfaces, respectively, a gate electrode provided on the insulation film such that the gate electrode extends to the first direction via the gate insulation film, a side-wall spacer provided respectively on both side walls of the gate electrode extending to the first direction, source/drain regions provided on the second side surfaces respectively, and source and drain electrodes that are provided respectively on the second side surfaces and are connected to the source/drain regions.

### CROSS-REFERENCE TO RELATED APPLICATIONS

This application is based upon and claims the benefit of priority from prior Japanese Patent Application No. 2004-183767, filed Jun. 22, 2004, the entire contents of which are incorporated herein by reference.

### BACKGROUND OF THE INVENTION

1. Field of the Invention

The present invention relates generally to a semiconductor device and a method of manufacturing the same, and more particularly to a FIN type MOSFET device having a pair of channels in planes vertical to the surface of a support substrate, and a method of manufacturing the same.

2. Description of the Related Art

With recent developments in a fine device structure of a semiconductor device, a further improvement in device performance is no longer expectable from a mere shrinkage in conventional MOSFET structures.

As a measure to break through the present situation, a planar complete-depletion type SOI-MOSFET has been proposed. In this SOI-MOSFET, an SOI (Silicon On Insulator) film with a thickness t_{SOI} is formed on a support substrate, with an SiO₂ film interposed. In the SOI film, source/drain regions and a gate electrode with a gate length Lg, which is formed between the source/drain regions with a gate insulation film interposed, are provided.

In this type of MOSFET, however, in order to provide a device with a gate length (Lg) of 20 nm or less, it is necessary to form the SOI film with a thickness t_{SOI} that is very uniform and thin over the substrate (10 nm or less). This requires a very high level of technical difficulty. It is also difficult to form a contact of, e.g. silicide film, on such a very thin SOI film. In this respect, too, the level of technical difficulty is high.

As a technique for eliminating the problem of the planar complete-depletion type SOI-MOSFET, there has been proposed a fin-type MOSFET (hereinafter referred to as “FINFET”) wherein channels are formed in planes vertical to the substrate surface.

FIGS. 10A and 10B show an FINFET 40. FIG. 10A is a sectional view, and FIG. 10B is a sectional view taken along line XB-XB in FIG. 10A. As shown in FIGS. 10A and 10B, an SiO₂ film 42 is provided on a support substrate 41, and a SOI film 43 is provided on the SiO₂ film 42. The SOI film 43 is shaped like a fin and protrudes from the SiO₂ film 42. A gate insulating film 44 and a gate electrode 45 are formed on either side of the SOI film 43. As in SOI-MOSFETs, the source and drain regions 47 have extension parts 46, which are formed in the SOI film 43. Silicide films 48 are formed on the source and drain regions 47, and an insulating cap layer 49 is provided on the gate electrode 45 provided between the source and drain regions 47. The gate electrode 45 has a length Lg. Insulating sidewalls 50 are provided on the sides of the gate electrode 45. An insulating film 51 is formed on the upper surface of the gate electrode 45.

In the FINFET structure, the thickness corresponding to the thickness of the SOI film of the planar SOI-MOSFET is a width t_{FIN} of the SOI layer that is processed in the fin shape. In addition, since gates are formed on both sides of the silicon layer (SOI layer), the required thickness becomes about double the thickness in the case of the planar type. For example, in the case of a device with a gate length (Lg) of 20 nm, the required fin width t_{FIN} is about 20 nm, and this value is actually feasible by processing.

In the FINFET shown in FIG. 10A, however, unlike the planar SOI-MOSFET, the distance between the source and drain regions, i.e. an effective gate length Leff becomes longer at a lower surface side Leff2 of the substrate than at an upper surface side Leff1 thereof. If such a problem arises, even if the operation speed of the device is to be increased by decreasing the gate length, a turn-on electric field would differ between upper and lower directions of the device and the switching speed could not be increased.

Jpn. Pat. Appln. KOKAI Publication No. 2003-298051 discloses that in a FINMOSFET a contact resistance is decreased by enlarging the contact region by selective epitaxial growth on the source and drain regions. Further, Jpn. Pat. Appln. KOKAI Publication No. 2003-163356 discloses that source and drain regions are formed by oblique ion implantation, and contacts therefor are formed along side walls of the fin.

In these prior-art FINFETs, however, the distance between the source and drain regions, i.e. the effective gate length Leff, is longer at a lower surface side Leff2 of the substrate than at an upper surface side Leff1 thereof. Consequently, the turn-on electric field differs in the upper and lower directions of the device, and the switching speed cannot be increased. Besides, the manufacturing methods are complex, and it is difficult to fabricate highly reliable devices with good reproducibility.

### BRIEF SUMMARY OF THE INVENTION

According to an aspect of the present invention, there is provided a semiconductor device comprising: a support substrate; an insulation film provided on the support substrate; a rectangular silicon island provided on the insulation film, the rectangular silicon island having first side surfaces mutually opposed in a first direction and second side surfaces mutually opposed in a second direction perpendicular to the first direction; an insulation layer provided on an upper surface of the silicon island; a gate insulation film provided on the mutually opposed first side surfaces, respectively; a gate electrode provided on the insulation film such that the gate electrode extends to the first direction via the gate insulation film; a side-wall spacer provided respectively on both side walls of the gate electrode extending to the first direction; source/drain regions provided on the second side surfaces, respectively; and source and drain electrodes provided respectively on the second side surfaces and connected to the source/drain regions.

According to another aspect of the present invention, there is provided a method of manufacturing a semiconductor device, comprising: preparing an SOI substrate including a support substrate, a first insulation film formed on the support substrate, and a silicon film formed on the first insulation film; forming a second insulation layer on the silicon film; successively removing the second insulation layer and the silicon film to form a convex silicon region having the second insulation layer on the convex silicon region; forming a gate electrode via a gate insulation film on both side surfaces of the silicon region; covering an upper surface of the gate electrode with a third insulation film and forming a side-wall spacer on both side surfaces of the gate electrode, respectively; selectively removing the silicon region exposed on a surface of the substrate to form a rectangular silicon island; introducing an impurity into both side surfaces of the exposed silicon island to provide a source region and a drain region; forming an interlayer insulation film over the surface of the substrate; forming contact holes for the source and drain regions in the interlayer insulation film; and filling a conductive material in the contact holes to form a source electrode and a drain electrode.

### BRIEF DESCRIPTION OF THE SEVERAL VIEWS OF THE DRAWING

FIG. 1 is a cross-sectional view that schematically illustrates a fabrication step of a fin-type MOSFET according to an embodiment;

FIGS. 2A and 2B are a plan view (A) and a cross-sectional view (B) that schematically illustrate a fabrication step of the fin-type MOSFET according to the embodiment;

FIGS. 3A to 3C are a plan view (A) and cross-sectional views (B, C) that schematically illustrate a fabrication step of the fin-type MOSFET according to the embodiment;

FIGS. 4A to 4C are a plan view (A) and cross-sectional views (B, C) that schematically illustrate a fabrication step of the fin-type MOSFET according to the embodiment;

FIGS. 5A to 5C are a plan view (A) and cross-sectional views (B, C) that schematically illustrate a fabrication step of the fin-type MOSFET according to the embodiment;

FIG. 6 is a perspective view that schematically illustrates a fabrication step of the fin-type MOSFET according to the embodiment;

FIGS. 7A to 7D are a plan view (A) and cross-sectional views (B, C, D) that schematically illustrate a fabrication step of the fin-type MOSFET according to the embodiment;

FIGS. 8A to 8D are a plan view (A) and cross-sectional views (B, C, D) that schematically illustrate a fabrication step of the fin-type MOSFET according to the embodiment;

FIG. 9 is a plan view that schematically illustrates a fabrication step of the fin-type MOSFET according to the embodiment; and

FIGS. 10A and 10B are sectional views showing a conventional fin-type MOSFET.

### DETAILED DESCRIPTION OF THE INVENTION

Referring now to FIGS. 1 to 9, a structure of a FINMOSFET according to an embodiment, as well as a method of manufacturing the FINMOSFET, will be described. As is shown in FIG. 1, an SOI substrate is prepared which comprises, for example, a support substrate 11 formed of silicon, a buried oxide film 12 formed on the support substrate 11, and a silicon (Si) film 13 formed on the oxide film 12.

A cap layer 14 that is formed of a silicon nitride (SiN) film is provided on the Si film 13. Using a lithography technique, a resist film is patterned to form a resist mask 15 on the cap layer 14.

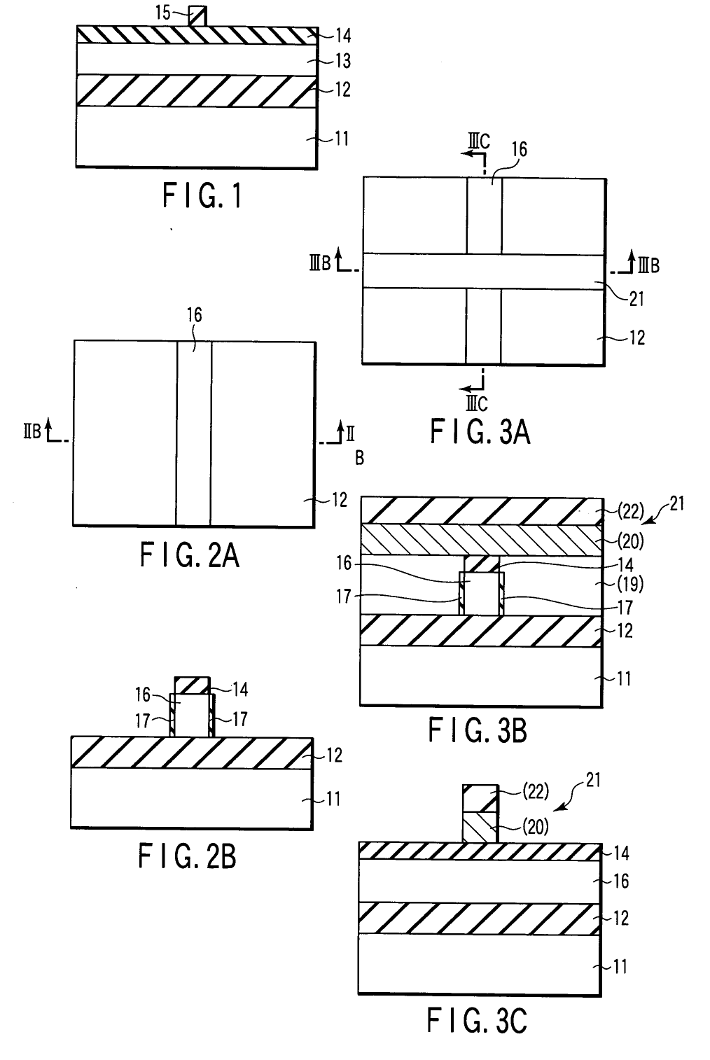

As is illustrated in FIGS. 2A and 2B, using the resist mask 15, the cap layer 14 and Si film 13 are successively removed, as in an ordinary process, to provide a convex silicon region 16 having the cap layer 14 on an upper surface thereof. Thereafter, a gate insulation film 17 is formed on both side surfaces of the convex silicon region 16.

As is shown in FIGS. 3A to 3c, a polysilicon film 19 is deposited by, e.g. CVD, on the oxide film 12 so as to bury the convex silicon region 16. The deposited polysilicon film 19 is planarized by, e.g. CMP. Then, an impurity, such as phosphorus (P), is introduced into the polysilicon film 19 by means of, e.g. ion implantation, and the resultant structure is subjected to heat treatment. Thereby, the polysilicon film 19 is made to have an n-type conductivity. Subsequently, a conductive film 20 of, e.g. tungsten silicide (WSix) is formed on the polysilicon film 19. An upper surface of the conductive film 20 is covered with an insulation film 22 of, e.g. SiN. Using a lithography technique and an RIE technique, the insulation film 22, the conductive film 20, and n-type polysilicon film 19 are patterned. Thus, a three-layer gate electrode 21 is formed so as to extend perpendicular to the convex silicon region 16.

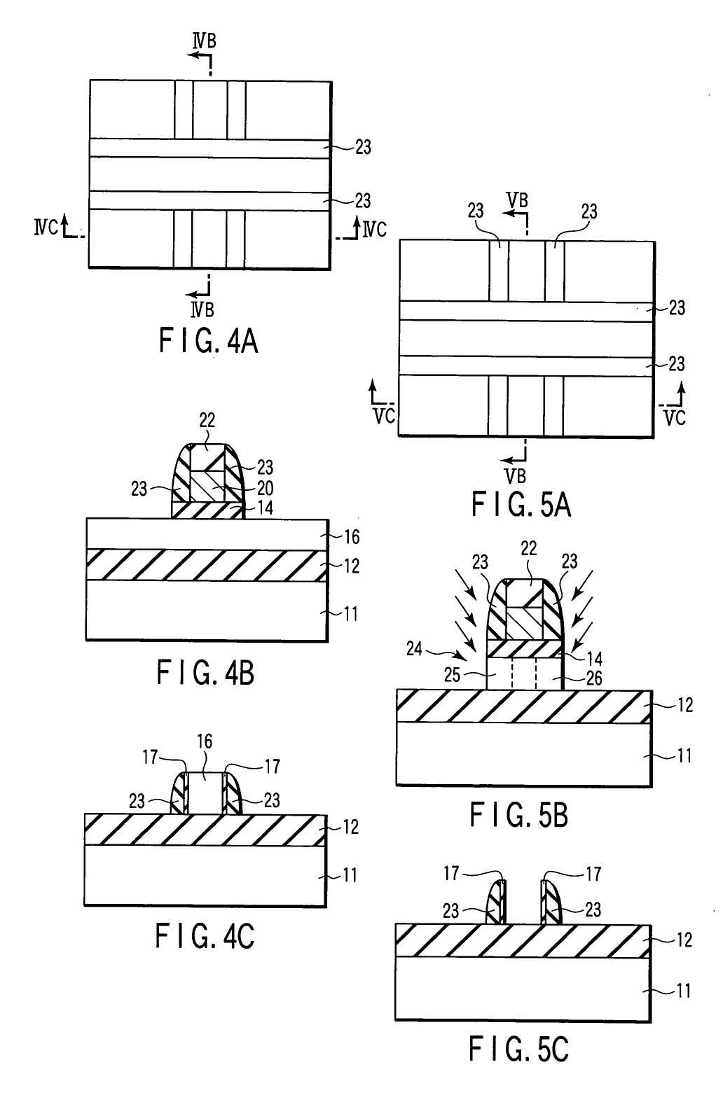

As illustrated in FIGS. 4A to 4C, a side-wall spacer 23, which is formed of a silicon nitride film, is provided on both side surfaces of the convex silicon region 16 and the gate electrode 21, respectively, as in an ordinary process. In this case, the silicon nitride cap layer 14 on the convex silicon region 16, which is present on the outside of the gate electrode 21 and silicon nitride side-wall spacers 23, is removed at the same time by the spacer processing.

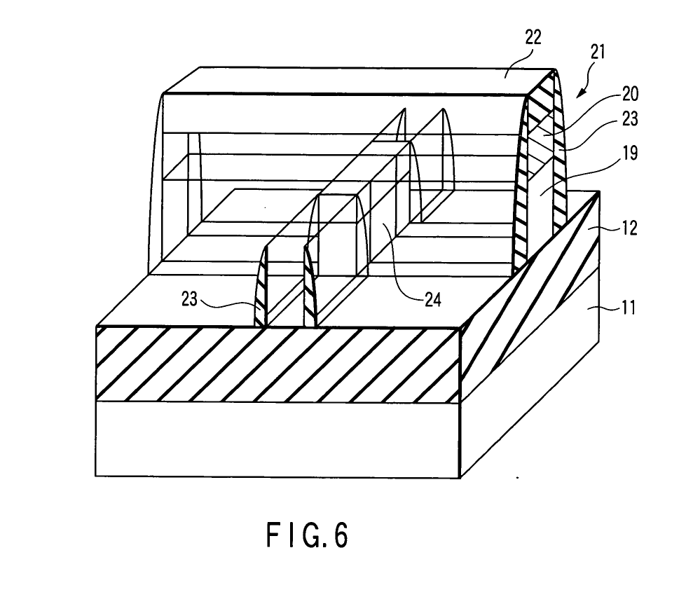

As is shown in FIGS. 5A to 5C and FIG. 6, the convex silicon region 16, which is present on the outside of the gate electrode 21 and the silicon nitride side-wall spacers 23 and is exposed to the substrate surface, is selectively removed. Thereby, a rectangular silicon island 24 is formed on the oxide film 12.

As is understood from the above description, mutually opposed first side surfaces and second side surfaces of the silicon island, which is exposed in this process, correspond to both side surfaces of the convex silicon region 16 on which the gate insulation films 17 are formed in FIGS. 2A and 2B, and two surfaces that intersect at right angles with these side surfaces. As is described later, on these side surfaces, source/drain regions 25 and 26 are formed in FIG. 5B. In this case, the first side surfaces and the second side surfaces are substantially vertical to the support substrate surface, and preferably at an angle of 80° to 95° to the support substrate surface.

Thereafter, as shown in FIG. 5B, n-type impurity, such as arsenic (As), is ion-implanted in both side surfaces of the exposed silicon island from obliquely above (5° to 45°), thereby forming an n⁺ type source region 25 and an n⁺ type drain region 26.

Specifically, when the n⁺ source/drain regions 25 and 26 are formed, the ion implantation is carried out at a slight angle inclined to the substrate from the vertical direction. Therefore, very shallow diffusion regions having a uniform impurity concentration distribution in the direction vertical to the substrate surface (i.e. uniform distribution in the gate length direction) can be formed, and the effective gate length Leff in the vertical direction of the convex silicon region 16 that serves as an active region will become substantially equal on the upper surface and bottom surface of the silicon island.

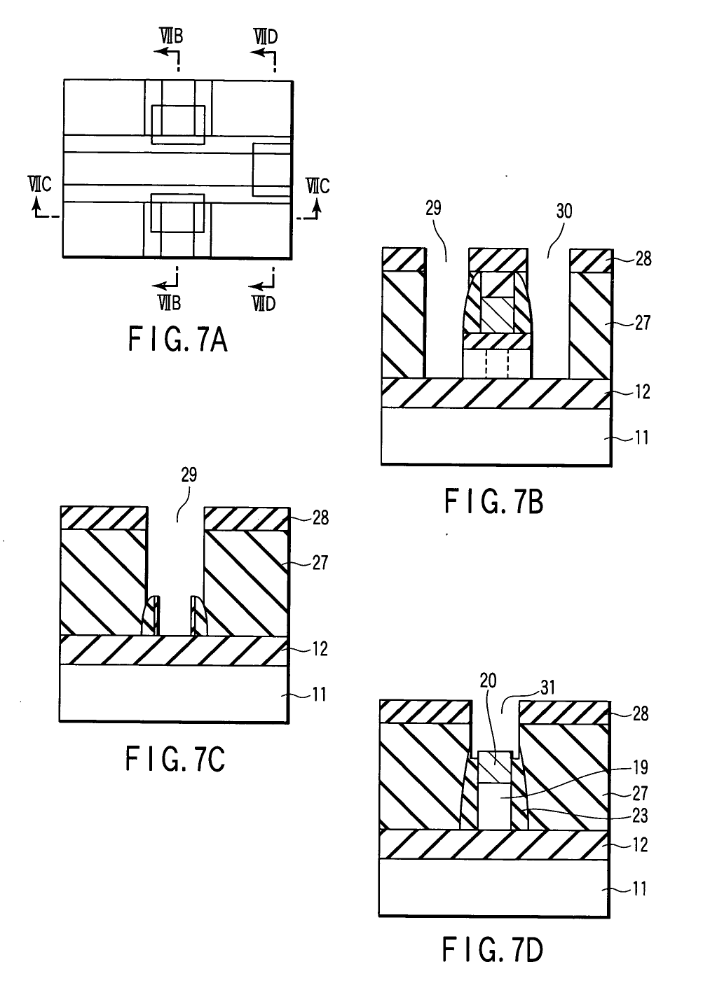

As is illustrated in FIGS. 7A to 7D, an insulation film 27, such as a silicon oxide film, is deposited on the substrate surface. The insulation film 27 is planarized by, e.g. CMP, and then an insulation film 28 is further deposited. Thereafter, using a resist pattern (not shown), contact holes 29, 30 and 31 are formed in the insulating films. The contact holes 29 and 30 expose substantially vertical side surfaces of the source region 25 and drain region 26. The contact hole 31 reaches the surface of the tungsten silicide (WSix) layer of the gate electrode 21.

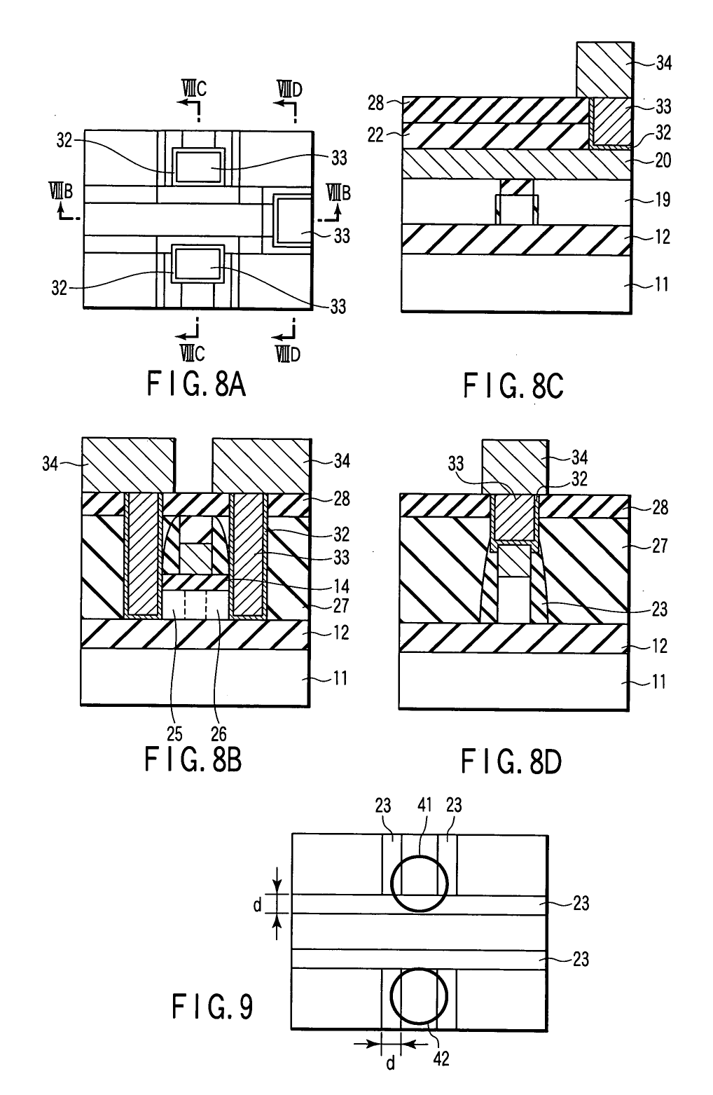

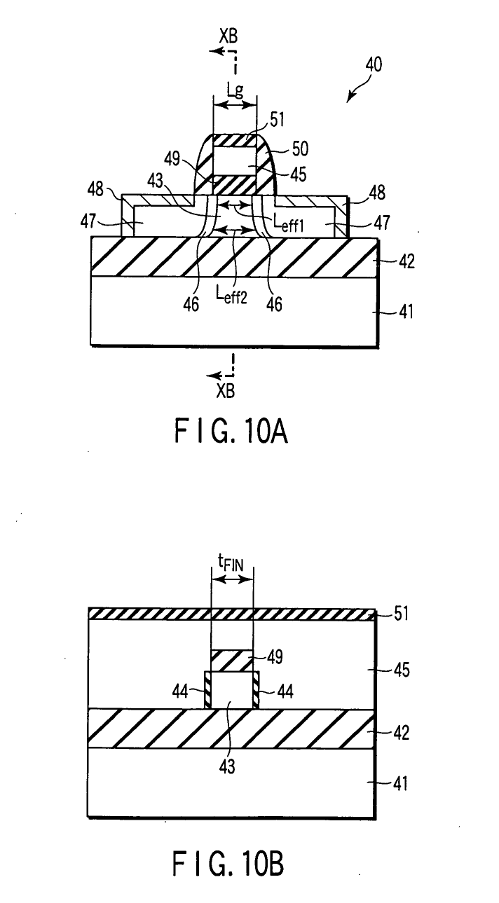

As is shown in FIGS. 8A to 8D, tungsten (W) is buried in the respective contact holes via barrier-metal Ti—TiN films 32, thereby forming contact plugs 33. On the contact plugs 33, upper wiring layers 34 are formed.

In FIG. 7A and FIG. 8A, the contract holes 29 to 31 are depicted such that they are quadrangle. However, if the size of these holes becomes the sub-micron order, the contact holes 29 to 31 will actually become substantially circular contact holes 41, 42, as shown in FIG. 9. In order to obtain good contact, the contact hole, like the contact hole 41, is formed so as to overlap at least ½ of the width d of the side-wall spacer 23.

If the contact hole, like the contact hole 42, is not formed to overlap at least ½ of the width d of the side-wall spacer 23, the contact plug 33, for example, will not be in good contact with the source region 24, leading to an increase in contact resistance.

As is clear from the above description, the impurity distribution in the source region and drain region in the vertical direction to the substrate surface becomes uniform, and the contact plugs that contact the source region and drain region are vertical to the substrate surface. Moreover, the effective gate length Leff in the width direction of the gate electrode is constant. Therefore, the performance of the device will be enhanced. In addition, a highly reliable device will be obtained by the simplified fabrication process.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a support substrate;
an insulation film provided on the support substrate;
a rectangular silicon island provided on the insulation film, the rectangular silicon island having first side surfaces mutually opposed in a first direction and second side surfaces mutually opposed in a second direction perpendicular to the first direction;
an insulation layer provided on an upper surface of the silicon island;
a gate insulation film provided on the mutually opposed first side surfaces, respectively;
a gate electrode provided on the insulation film such that the gate electrode extends to the first direction via the gate insulation film;
a side-wall spacer provided respectively on both side walls of the gate electrode extending to the first direction;
source/drain regions provided on the second side surfaces, respectively; and
source and drain electrodes provided respectively on the second side surfaces and connected to the source/drain regions.

2. The semiconductor device according to claim 1, wherein the source/drain regions have a uniform impurity concentration distribution in a direction vertical to a surface of the substrate.

3. The semiconductor device according to claim 1, wherein the source and drain electrodes are connected to the source/drain regions in planes that are substantially vertical to a surface of the substrate.

4. The semiconductor device according to claim 1, wherein the first and second side surfaces are substantially vertical to the surface of the substrate, and are at an angle of 80° to 95° to the surface of the substrate.

5. The semiconductor device according to claim 1, wherein an impurity concentration distribution in the source/drain region has no concentration gradient in a direction vertical to the surface of the substrate, and has a concentration gradient in a direction perpendicular to both the surface of the substrate and the plane with the gate insulation film.

6. The semiconductor device according to claim 1, wherein a gate length is 5 to 30 nm and a thickness of the silicon island that is sandwiched between the gate insulation films is 5 to 30 nm.

7. The semiconductor device according to claim 1, wherein each of contact holes for the source/drain regions is formed to overlap at least ½ of a width d of each of the side-wall spacers provided on both side surfaces of a gate structure and a gate wiring structure.

8. The semiconductor device according to claim 1, wherein one selected from the group consisting of tungsten (W) and a tungsten compound is buried in the contact holes via a stacked film that serves as a barrier metal and comprises a Ti film and a TiN film.

9. A method of manufacturing a semiconductor device, comprising:
preparing an SOI substrate including a support substrate, a first insulation film formed on the support substrate, and a silicon film formed on the first insulation film;
forming a second insulation layer on the silicon film;
successively removing the second insulation layer and the silicon film to form a convex silicon region having the second insulation layer on the convex silicon region;
forming a gate electrode via a gate insulation film on both side surfaces of the silicon region;
covering an upper surface of the gate electrode with a third insulation film and forming a side-wall spacer on both side surfaces of the gate electrode, respectively;
selectively removing the silicon region exposed on a surface of the substrate to form a rectangular silicon island;
introducing an impurity into both side surfaces of the exposed silicon island to provide a source region and a drain region;
forming an interlayer insulation film over the surface of the substrate;
forming contact holes for the source and drain regions in the interlayer insulation film; and
filling a conductive material in the contact holes to form a source electrode and a drain electrode.

10. The method according to claim 9, wherein when the source drain regions are formed, an impurity is ion-implanted from a oblique direction into both side surfaces of the silicon island.

11. The method according to claim 10, wherein the ion implantation is performed at an angle of 5° to 45°.

12. The method according to claim 10, wherein the ion implantation is performed in a plurality of directions, with a fixed angle between an ion beam and a line vertical to the surface of the support substrate.
